(19) United States
(12) Patent Application Publication
(10) Pub. No.: US 2013/0294026 A1
(43) Pub. Date: Nov. 7, 2013

(54) ELECTRONICS COMPARTMENT

(71) Applicants: Juha TUOMOLA, Helsinki (FI); Brian BALDWIN, Waukesha, WI (US)

(72) Inventors: Juha TUOMOLA, Helsinki (FI); Brian BALDWIN, Waukesha, WI (US)

(73) Assignee: ABB Oy, Helsinki (FI)

(21) Appl. No.: 13/465,645

(22) Filed: May 7, 2012

(51) Int. Cl. H05K 7/20

(52) U.S. Cl. 361/692

(57) ABSTRACT

An electronics compartment is disclosed with a component space which is sealed off from a surrounding environment by walls. An internal panel is arranged in the component space along a wall of the electronics compartment for delimiting an internal channel between the wall and the internal panel. An external panel is arranged along a same wall of the electronics compartment as the internal panel, but outside the component space for delimiting an external channel between the wall and the external panel. Air flowing in the internal channel and external channel can improve heat transfer through the wall, and cool electric components in the component space.

### FIELD OF THE INVENTION

An electronics compartment, and solutions for cooling the interior of an electronics compartment are disclosed.

### BACKGROUND

Known electronics compartments have walls which seal off a component space from the surrounding environment. In a known solution the temperature of the air inside the component space rises clue to heat generated by electric components present in the component space. The heated air is in contact with the walls of the component space and consequently heat is conducted through the walls to the surrounding environment of the component space.

However, known electronics compartments can have insufficient cooling. Due to the insufficient cooling, the temperature inside the component space may rise to a level where damage may occur.

### SUMMARY

An electronics compartment is disclosed comprising: a component space which is sealed off from a surrounding environment by walls of the electronics compartment; an internal panel arranged in the component space along a wall of the electronics compartment for delimiting an internal channel between the wall and the internal panel; a first inlet in a vicinity of a first end of the internal channel for allowing air to enter the internal channel from a space located on an opposite side of the internal panel in relation to the internal channel; a first outlet in a vicinity of a second end of the internal channel for allowing air to exit from the internal channel to the space located on the opposite side of the internal panel in relation to the internal channel; an external panel arranged along a same wall of the electronics compartment as the internal panel, but outside the component space for delimiting an external channel between the wall and the external panel, the wall being air-tight at least between the external channel and the internal channel for separating the external channel from the internal channel by preventing airflow between these channels; a second inlet in a vicinity of a first end of the external channel for allowing air to enter the external channel from the surrounding environment of the electronics compartment; and a second outlet in a vicinity of a second end of the external channel for allowing air to exit from the external channel to the surrounding environment of the electronics compartment.

### BRIEF DESCRIPTION OF DRAWINGS

In the following, exemplary embodiments of the present invention will be described in closer detail by way of example and with reference to the attached drawings, in which:

FIGS. 1 to 4 illustrate a first exemplary embodiment of an electronics compartment;

FIGS. 5 to 8 illustrate a second exemplary embodiment of an electronics compartment;

FIG. 9 illustrates a third exemplary embodiment of an electronics compartment; and

FIG. 10 illustrates a fourth exemplary embodiment of an electronics compartment.

### DETAILED DESCRIPTION

Exemplary embodiments as disclosed herein include a solution for providing adequate cooling to an electronics compartment. An exemplary electronics compartment can include: a component space which is sealed off from the surrounding environment by walls of the electronics compartment, an internal panel arranged in the component space along a wall of the electronics compartment for delimiting an internal channel between the wall and the internal panel, a first inlet in the vicinity of a first end of the internal channel for allowing air to enter the internal channel from a space located on an opposite side of the internal panel in relation to the internal channel, and a first outlet in the vicinity of a second end of the internal channel for allowing air to exit from the internal channel to the space located on the opposite side of the internal panel in relation to the internal channel. An external panel can be arranged along the same wall of the electronics compartment as the internal panel, but outside the component space for delimiting an external channel between the wall and the external panel, the wall being air-tight at least between the external channel and the internal channel for separating the external channel from the internal channel by preventing airflow between these channels. A second inlet in the vicinity of a first end of the external channel can allow air to enter the external channel from the surrounding environment of the electronics compartment, and a second outlet in the vicinity of a second end of the external channel can allow air to exit from the external channel to the surrounding environment of the electronics compartment.

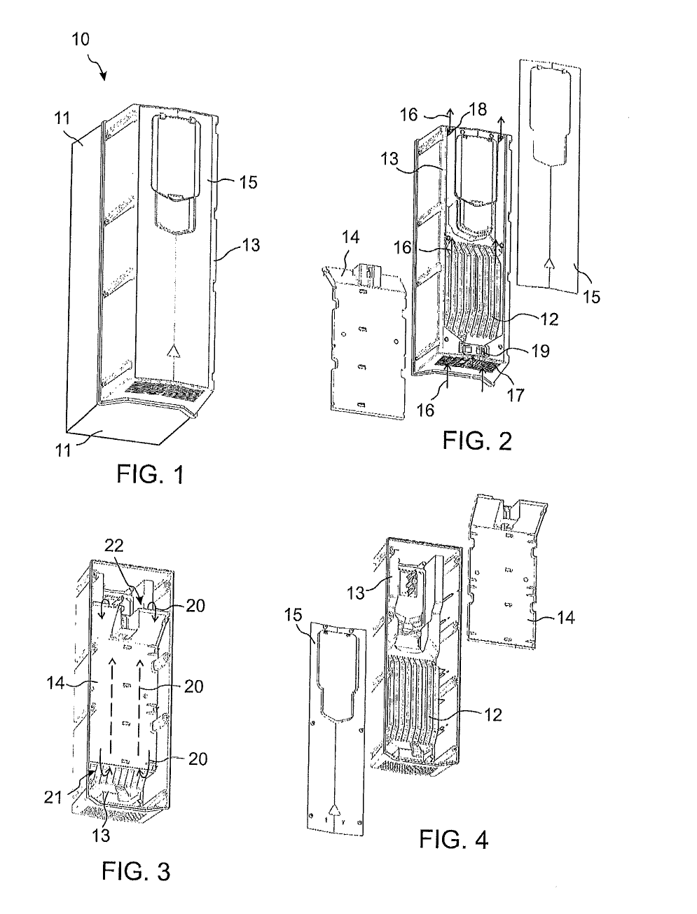

FIGS. 1 to 4 illustrate a first embodiment of an electronics compartment 10.

FIG. 1 illustrates the electronics compartment 10 once assembled. The electronics compartment may be an electronics compartment for a motor drive, such as a frequency converter, for instance. The electronics compartment 10 can include a plurality of walls 11 and 13 which seal off the interior of a component space from the surrounding environment. In the following it will, by way of example, be assumed that the walls 11 and 13 together form an air tight barrier between the inside of the component space and the surrounding environment.

In the illustrated example, one of the walls 13 is implemented as a removable cover facilitating installation of electric components in the component space, for instance. This wall 13 of the component space is utilized as an air-to-air heat exchanger for transferring heat from the inside of the component space to the surrounding environment outside the component space.

The electronics compartment 10 includes an external panel 15 arranged along the wall 13 on the outside of the component space for delimiting an external channel 16 between the wall 13 and the external panel 15. The external panel 15 is illustrated as being attached to the wall 13 in FIG. 1 while FIG. 2 is an exploded view illustrating the external panel 15 and wall 13 detached from each other. The external channel 16 is illustrated by arrows indicating airflow through the external channel 16. A second inlet 17 in the lower part of the wall 13 allows air to enter the external channel 16. However, due to the air-tight design of the wall 13, air can be prevented from entering the component space via the second inlet 17 or other parts of the external channel. A second outlet 18 (or outlets as in the illustrated example) in the upper part of the wall 13 allows air to exit from the external channel 16 to the surrounding environment. Consequently air may flow between the wall 13 and the external panel 15, due to which the outside surface of the wall 13 is efficiently cooled. In order to improve the airflow, an external fan 19 may be utilized for generating an airflow through the external channel 16,

In the illustrated embodiment the surface area of the wall 13 is increased by protrusions and recesses 12. Therefore, transfer of heat from the outer surface of the wall 13 to the air in the external channel 16 can be improved.

FIGS. 3 and 4 illustrate the inside of the wall 13. An internal panel 14 is arranged along the inside of the wall 13. In FIG. 3 the internal panel 14 is shown as being attached to the wall 13 and FIG. 4 illustrates an exploded view where the internal panel 14 is detached from the wall 13.

The internal panel 14 delimits an internal channel 20 between the wall 13 and the internal panel 14. In the figures the internal channel 20 is illustrated by arrows indicating airflow through the internal channel 20. A first inlet 21 is arranged at a lower end of the internal panel 14 for allowing air to enter the internal channel 20 from a space located on an opposite side of the internal panel 14 in relation to the internal channel 20. Similarly, a first outlet 22 is arranged at an upper end of the internal panel 14 for allowing air to exit from the internal channel 20 to the space located on the opposite side of the internal panel 14 in relation to the internal channel 20. Consequently, air can flow from the component space via the first inlet 21 into the internal channel 20 and from the internal channel 20 via the first outlet 22 into the component space. In this way, air which is heated by electric components in the component space may flow into the internal channel where the air is cooled as heat is transferred through the wall 13 into the external channel 16. The air-tight wall 13 separates the external channel from the internal channel and prevents flow of air between these channels. The air exiting the internal channel 20 has, therefore, a lower temperature than the air entering the internal channel. Components in the component space are, therefore, cooled due to the airflow. A fan may be utilized in order to cause air to flow through the internal channel 20. Such a fan may be located in the internal channel 20 or in the component space.

The protrusions and recesses 12 provided in the wall 13 in order to increase the outside surface area of the wall 13 are present also on the inside of the wall 13. Consequently, the inside surface area of the wall is increased and the transfer of heat from the air in the internal channel to the inner surface of the wall 13 can be improved.

One exemplary alternative to manufacture the wall 13, the internal panel 14 and the external panel 15 is injection molding of a suitable plastic material. However, in practice, the external panel 15 acts as a cosmetic outer surface of the electronics compartment, in which case it may also have other functional tasks than to provide the external channel only. Therefore, some parts of the external panel or the entire external panel may be manufactured in a different way and of a different material than plastics.

In the embodiment illustrated in FIGS. 1 to 4, it has, by way of example, been assumed that the internal panel 15 is a separate part attached to the inside of the wall 13 only for the purpose of providing the internal channel 20. However, this is only one possible exemplary embodiment. Alternatively, it is, for example, possible for a part provided in the electronics compartment for a completely different reason to have a surface acting as the internal panel. In that case, the internal panel may be a printed circuit board or a base plate for receiving electric components, for instance.

In FIGS. 1 to 4 it has, by way of example, been assumed that the airflow in the internal channel 16 and the airflow in the external channel 20 (on opposite sides of the same wall 13) are directed in the same direction. Therefore, the arrows indicate that the air flows upwards both in the internal channel and in the external channel. This is, however, only an example. In practice, it may, in some implementations, be advantageous to let the airflow in opposite directions in the internal and external channels.

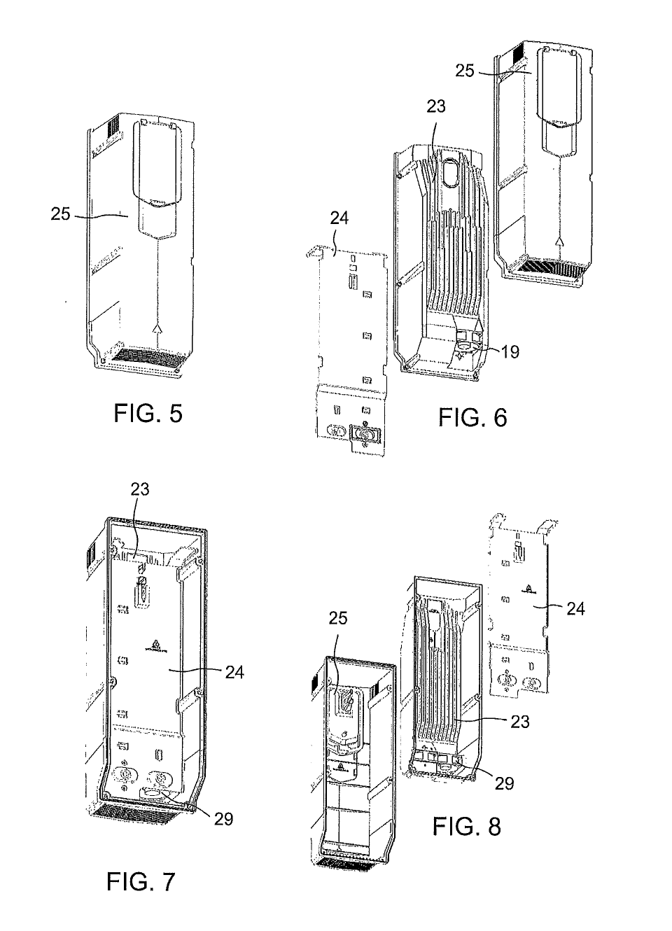

FIGS. 5 to 8 illustrate a second exemplary embodiment of an electronics compartment. The embodiment of FIGS. 5 to 8 is very similar to the embodiment of FIGS. 1 to 4, and therefore the embodiment of FIGS. 5 to 8 will mainly be explained by pointing out the differences between these embodiments.

In FIGS. 5 to 8 the outer panel 25 is shaped to almost completely cover the outside of the wall 23. Additionally, in this embodiment an internal fan 29 is provided in the internal channel between the internal panel 24 and the wall 23 in order to generate an airflow in the internal channel.

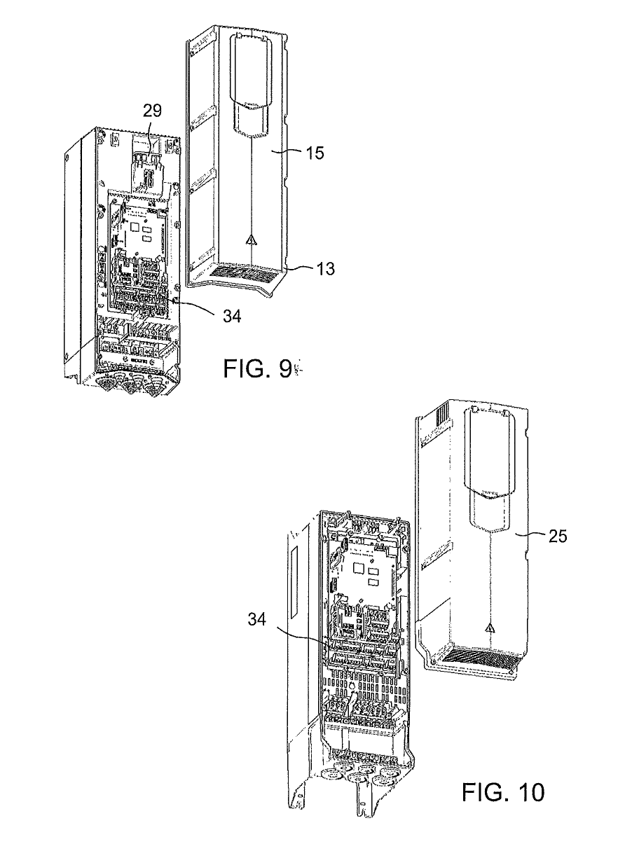

FIG. 9 illustrates a third exemplary embodiment of an electronics compartment. The embodiment of FIG. 9 is very similar to the embodiment of FIGS. 1 to 4, and therefore the embodiment of FIG. 9 will mainly be explained by pointing out the differences between these embodiments.

In the embodiment of FIG. 9 the wall 13 and the external panel 15 are implemented as in the embodiment of FIGS. 1 to 4. However, the internal panel 34 includes (e.g., consists entirely or partially of) a printed circuit board or a base plate carrying electric components. FIG. 9 also illustrates the internal fan 29 arranged in an upper part of the electronics compartment for circulating air through the internal channel which is delimited by the wall 13 and the internal panel 34.

FIG. 10 illustrates a fourth exemplary embodiment of an electronics compartment. The embodiment of FIG. 10 is very similar to the embodiment of FIGS. 5 to 8, and therefore the embodiment of FIG. 10 will mainly be explained by pointing out the differences between these embodiments.

In the embodiment of FIG. 10 the wall 23 and the external panel 25 are implemented as in the embodiment of FIGS. 5 to 8. However, the internal panel 34 includes (e.g., consists entirely or partially of) a printed circuit board or base plate carrying electric components. An internal fan for generating an airflow in the internal channel may be arranged behind (under in FIG. 10) the illustrated internal panel 34.

It is to be understood that the above description and the accompanying figures are only intended to illustrate examples of the present invention. It will be apparent to those skilled in the art that the invention can be varied and modified without departing from the scope of the invention.

Thus, it will be appreciated by those skilled in the art that the present invention can be embodied in other specific forms without departing from the spirit or essential characteristics thereof. The presently disclosed embodiments are therefore considered in all respects to be illustrative and not restricted. The scope of the invention is indicated by the appended claims rather than the foregoing description and all changes that come within the meaning and range and equivalence thereof are intended to be embraced therein.

1. An electronics compartment comprising:
a component space which is sealed off from a surrounding environment by walls of the electronics compartment;
an internal panel arranged in the component space along a wall of the electronics compartment for delimiting an internal channel between the wall and the internal panel;
a first inlet in a vicinity of a first end of the internal channel for allowing air to enter the internal channel from a space located on an opposite side of the internal panel in relation to the internal channel;
a first outlet in a vicinity of a second end of the internal channel for allowing air to exit from the internal channel to the space located on the opposite side of the internal panel in relation to the internal channel;
an external panel arranged along a same wall of the electronics compartment as the internal panel, but outside the component space for delimiting an external channel between the wall and the external panel, the wall being air-tight at least between the external channel and the internal channel for separating the external channel from the internal channel by preventing airflow between these channels;
a second inlet in a vicinity of a first end of the external channel for allowing air to enter the external channel from the surrounding environment of the electronics compartment; and
a second outlet in a vicinity of a second end of the external channel for allowing air to exit from the external channel to the surrounding environment of the electronics compartment.

2. The electronics compartment according to claim 1, wherein the component space comprises:
an internal fan for generating an airflow through the internal channel.

3. The electronics compartment according to claim 1, wherein the electronics compartment comprises:
an external fan for generating an airflow through the external channel.

4. The electronics compartment according to claim 1, wherein the wall which delimits the internal channel with the internal panel and which delimits the external channel with the external panel is an injection-molded plastic part.

5. The electronics compartment according to claim 1, wherein the internal panel is a printed circuit board or a base plate for receiving electric components.

6. The electronics compartment according to claim 1, wherein the internal panel is a part of a device provided in the electronics compartment.

7. The electronics compartment according to claim 1, wherein the wall between the internal channel and the external channel comprises:
protrusions and recesses for increasing a surface area of the wall configured to improve transfer of heat from the internal channel to the external channel.

8. The electronics compartment according to claim 1, wherein the electronics compartment is an electronics compartment for a motor drive.
